(19) United States
(12) Patent Application Publication
(10) Pub. No.: US 2006/0228903 A1
(43) Pub. Date: Oct. 12, 2006

(54) Precursors for the deposition of carbon-doped silicon nitride or silicon oxynitride films

(76) Inventors: Michael L. McSwiney, Scappoose, OR (US); Mengcheng Lu, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/096,057

(22) Filed: Mar. 30, 2005

(51) Int. Cl. H01L 21/31; H01L 21/469

(52) U.S. Cl. 438/778

(57) ABSTRACT

A process for fabricating carbon doped silicon nitride layers is described. By adjusting the amount of carbon in adjacent regions, selective etching of the silicon nitride regions can occur. Several precursors for the introduction of carbon into the silicon nitride film, are described.

### FIELD OF THE INVENTION

The invention relates to the field of insulative layers in semiconductor devices.

### PRIOR ART AND RELATED ART

Silicon nitride (Si₃N₄), sometimes referred to as nitride, is a hard, dense insulator with a high melting point. Even a thin nitride layer, unlike a silicon dioxide layer, provides a barrier for most materials, and even hydrogen diffuses very slowly in nitride. Consequently, silicon nitride prevents oxidation of underlying silicon and has been used for many years to form local oxidation regions on silicon. Another of its many uses is as an etchant stop layer for both wet and plasma etching. Often, nitride is used as a hard mask material since it is such a good etch stop.

In some applications, a plasma deposited silicon nitride film includes oxygen to form silicon oxynitride. Among its uses is the insulation of a gate in a field-effect transistor from its channel region.

Numerous commercially available etchants are used to etch silicon nitride films. Some of these etchants are based on fluoride chemistry and others are derived from phosphoric acid. Etchants provide good selectivity of silicon nitride to, for instance, silicon dioxide and silicon. Nitride however, has disadvantages in that it is relatively expensive and difficult to etch, and in some instances, the selectivity to, for example, silicon is not as high as needed. Also, in a plasma etching process, plasma charging damage may occur.

Often nitride and oxynitride films are deposited using a silane precursor as the source of silicon. Ammonia and nitrogen are most often used as the nitrogen source. Nutritious oxide is sometimes used as the oxygen source for oxynitride. Conventional plasma enhanced chemical vapor deposition (PECVD) is used to deposit these films. Gas flows and process conditions are varied to change the nitride-to-oxide ration to satisfy photolithography, etching, electrical and other material requirements in oxynitride. Fluorine-doped silicon nitride and silicon boron nitride films have also been proposed, see for example, Plasma-Assisted Chemical Vapor Deposition of Dielectric Thin Films for ULSI Semiconductor Circuits, by Cote et al (www.research.ibm.com/journal,1999).

For other related art, see “METHOD AND APPARATUS FOR LOW TEMPERATURE SILICON NITRIDE DEPOSITION,” Ser. No. 10/750,062; “LOW-TEMPERATURE SILICON NITRIDE DEPOSITION,” Ser. No. 10/631,627; FORMING A SILICON NITRIDE FILM,” Ser. No. 10/764,193, and “SELECTIVELY ETCHING SILICON NITRIDE,” Ser. No. 10/761,392, all assigned to the assignee of the present application.

### BRIEF DESCRIPTION OF THE DRAWINGS

FIG. 1 is a cross-sectional, elevation view of a semiconductor substrate and a structure having two silicon nitride regions formed from different silicon nitride material.

FIG. 2 is a cross-sectional view of a deposition chamber showing the delivery of precursors, oxygen and ammonia to the chamber.

FIG. 3 illustrates several alkyl silane precursors.

FIG. 4 illustrates several alkyl polysilane precursors.

FIG. 5 illustrates several halogenated alkyl silane precursors

FIG. 6 illustrates several silyl methane precursors.

FIG. 7 illustrates several silyl ethanes and ethylene precursors.

### DETAILED DESCRIPTION

A method for fabricating insulative regions and their use in an integrated circuit is described. In the following description, numerous specific details such as specific precursors are described in order to provide a thorough understanding of the present invention. It will be apparent to one skilled in the art that the present invention may be practiced without these specific details. In other instances, well-known processes, etchants and deposition techniques are not described in detail in order not to unnecessarily obscure the present invention.

As mentioned earlier, silicon nitride films and silicon nitride films with oxygen, referred to as silicon oxynitride films, are prominently used in the fabrication of semiconductor devices, particularly integrated circuits. These materials exhibit the characteristics of a refractory material, have a relatively high dielectric constant (e.g., 6-8), have a relatively low coefficient of thermal expansion, and are an excellent diffusion barrier. Yet, the difficulty in etching these materials, in some cases, limits their usefulness. Furthermore, the relatively high dielectric constant can be detrimental to device performance in some cases.

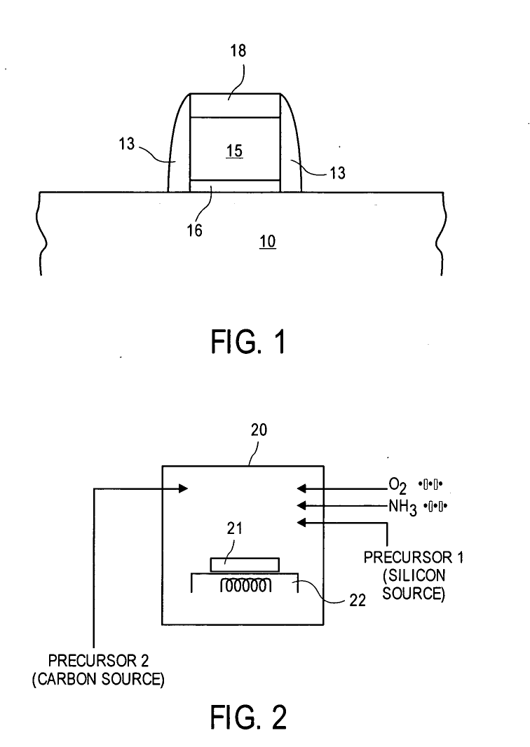

In FIG. 1, a cross-sectional, elevation view of a silicon substrate 10 is shown along with a gate insulator 16, a gate 15, and silicon nitride sidewall spacers 13 disposed on the sides of gate 15. Assume for purposes of discussion that the gate 15 was formed in alignment with an overlying hard mask 18 formed from a silicon nitride layer. In a typical process flow after the gate 15 is formed, a conformal layer of silicon nitride is deposited over the structure and anisotropically etched to form the sidewall spacers 13. (The various doping steps accompanying the structure to form source and drain regions in the substrate 10 is not discussed.) In some technologies, for instance, gate replacement technology, it is desirable to remove the hard mask 18 and leave in place the spacers 13. It is difficult to remove the hard mask 18 without altering the size and shape of the spacers 13. Ideally, the mask 18 should be removed without significantly altering the sidewall spacers 13.

As described below, the hard mask 18 may be formed from a first composition of silicon nitride and the sidewall spacers 13 from a second composition of silicon nitride. The difference between the first and second compositions is the amount of carbon doping in the respective compositions. Typically, more carbon doping in a layer causes it to etch more quickly. Consequently, if mask 18 has more carbon doping than the sidewall spacers 13, it may be etched more quickly than the sidewall spacers 13 in the presence of an etchant. Thus, the hard mask 18 can be removed more readily without damage to the sidewall spacers 13. In fact, if the mask 18 etches more quickly, part, if not all of it, may be removed at the time that the layer from which the sidewall spacers 13 are formed is etched.

Therefore, by using more carbon doping in one nitride layer or region compared to another, selected etching between the silicon nitride layers or regions can occur when both are subjected to the same etchant. The same is true where one or both of the layers or regions is silicon oxynitride.

In the example of FIG. 1, the material used to form the silicon nitride sidewall spacers 13 may have no carbon doping (zero doping), whereas the hard mask 18 may have, by way of example, 20% carbon doping (by atomic weight).

As described below, in addition to the somewhat standard precursors used for formation of silicon nitride, a second precursor is used to supply carbon to provide a carbon doped silicon nitride layer. Accordingly, the amount of the second precursor is adjusted for one (or both) of the layers or regions to allow one to be etched more readily than the other. This etching can be done in the presence of standard etchants (wet or dry) used for etching silicon nitride and silicon oxynitride.

Referring to FIG. 2, a deposition chamber 20 is illustrate which may be a PECVD chamber 20 having a heated chuck 22 upon which a wafer 21 is disposed

A first precursor (precursor 1), which provides a source of silicon, is delivered to the chamber 20. Common silicon nitride or low-temperature silicon nitride precursors which can be applied to this process include, but are not limited to, halogenated silanes and disilanes (which include, but are not limited to dichlorosilane and hexachlorodisilane), amino silanes (which include, but are not limited to bis (t-butyl amino) silane and tetrakis (dimethyl amino) silane), cyclodisilazanes (which include, but are not limited to 1,3-diethyl-1,2,3,4-tetramethylcyclodisilazane, 1,3-divinyl-1,2,3,4-tetramethylcyclodisilazane, and 1,1,3,3-tetrafluoro-2,4-dimethylcyclodisilazane), linear and branched silazanes (which include, but are not limited to hexamethyldisilazane and tris(trimethylsilyl)amine), azidosilanes, substituted versions of 1,2,4,5-tetraaza-3,6-disilacyclohexane (which include, but are not limited to 3,6-bis(dimethylamino)-1,4-ditertiarybutyl-2,5-dimethyl-1,2,4,5-tetraaza-3,6-disilacyclohexane and 3,6-bis(tertiarybutylamino)-1,4-ditertiarybutyl-1,2,4,5-tetraaza-3,6-disilacyclohexane), and silyl hydrazines (which include, but are not limited to 1-silylhydrazine, 1,2-disilylhydrazine, 1,1,2-trisilylhydrazine, and 1,1,2,2-tetrasilylhydrazine).

Nitrogen is also delivered to the chamber 20 through a nitrogen containing gas or precursor. Typically, the nitrogen is supplied from ammonia, hydrazine, amines, etc.

Particularly where silicon oxynitride is being deposited, additional oxygen can be provided to the reaction from the use of an oxygen source which includes sources such as oxygen, ozone, and/or N₂O.

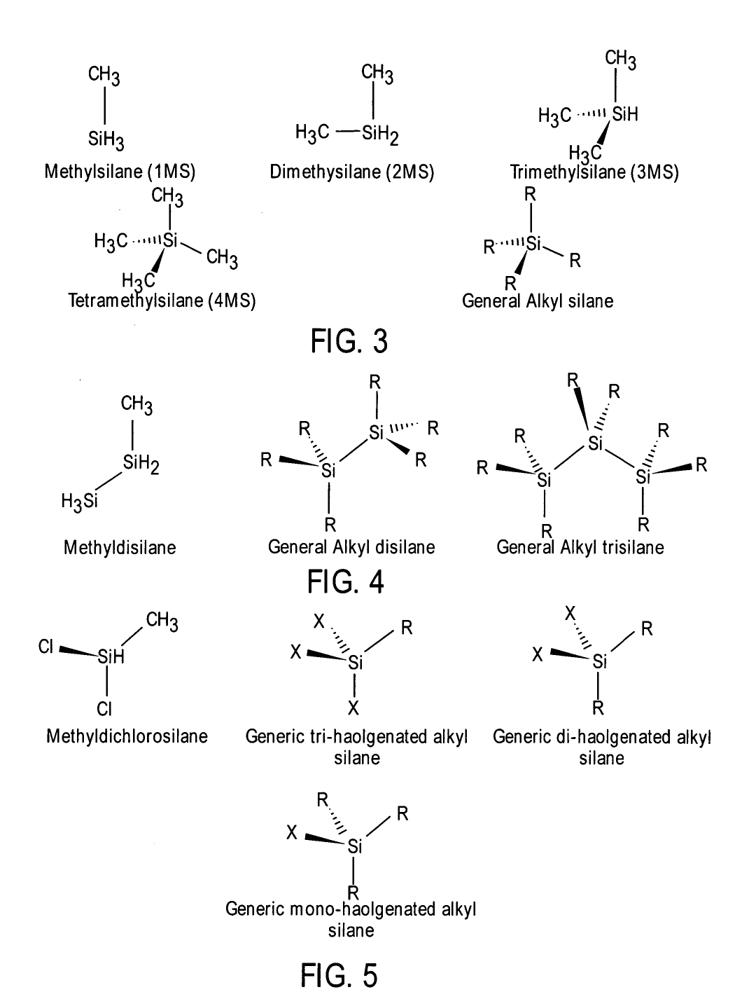

FIGS. 3 through 7 show second examples of a precursor delivered to the chamber 20. These precursors, which may also be silane based, are used to provide a source of carbon and may provide a source of additional silicon.

FIG. 3 shows one class of compounds, useful to add carbon doping into a silicon nitride or silicon oxynitride film, namely alkyl silanes. These compounds all have the general formula SiR₄ were R is any ligand including but not limited to hydrogen, alkyl, and aryl (all R groups are independent). Examples of this class of compounds include methylsilane (1MS), dimethylsilane (2MS), trimethylsilane (3MS), and tetramethylsilane (4MS).

FIG. 4 shows a closely related class of compounds, the alkyl polysilanes which include, but are not limited to substituted disilanes and trisilanes. Substituted disilanes have the general formula Si₂R, and substituted trisilanes have the general formula Si₃R₈. In all cases, R is any ligand including but not limited to hydrogen, alkyl, and aryl (all R groups are independent). Examples of this class of compounds include methyldisilane and hexamethyldisilane (HMDS).

FIG. 5 shows another related class of compounds, halogenated alkyl silanes. These compounds have a variety of general formulas based on the number of halogens incorporated into the molecule. The general formulas are: SiXR₃ for one halogen incorporation, SiX₂R₂ for a two halogen incorporation, and SiX₃R for three halogen incorporation. In case of one and two halogen incorporations, R is any ligand including but not limited to hydrogen, alkyl, and aryl (all R groups are independent). In the three halogen case only, R cannot be hydrogen, but it can be alkyl, aryl, or other carbon containing ligand. In all cases X is any halogen (F, Cl, Br, or I).

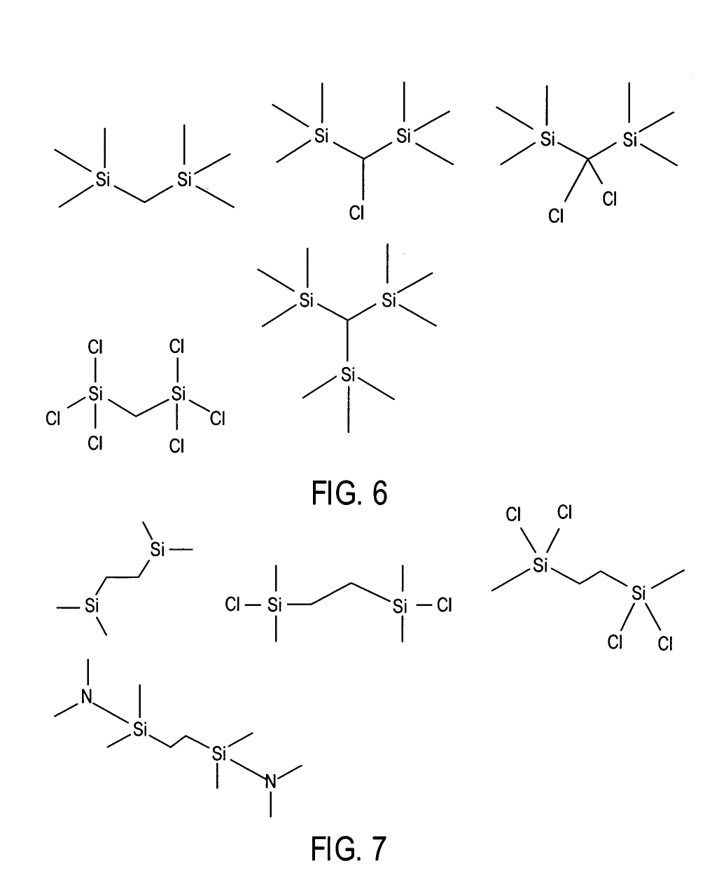

FIG. 6 shows carbon bridged silane precursors which can be used. These include, but are not limited to, silyl methanes.

FIG. 7 shows silyl ethanes/ethylene precursors.

The precursors can be delivered through one of several methods, encompassing any currently available precursor delivery technology. Volatile solids and liquid precursors can simply use vapor draw at elevated temperatures. Volatile liquids can also be bubbled. Any liquid precursor can be delivered via direct liquid injection. Involatile solid precursors can be dissolved in an appropriate solvent (such as toluene or other hydrocarbon) and delivered via direct liquid injection. Compatible liquid precursors can be pre-mixed into a cocktail and delivered via direct liquid injection. Solution compatible precursors can be dissolved in an appropriate solvent (which include, but are not limited to hexanes, toluene, etc.) and delivered via direct liquid injection. Gases can be delivered through direct gas lines regulated by a mass flow controller either independently or through a pre-tool blending system.

By adjusting the flow of the first and second precursor, the amount of carbon doping in the silicon nitride or silicon oxynitride films can be adjusted. Additionally, by adjusting the oxygen flow or other source of oxygen, the composition of the silicon oxynitride film can further be controlled.

Thus, the deposition and use of a carbon doped silicon nitride and silicon oxynitride films in a semiconductor process has been described.

What is claimed is:

1. A method for forming an insulative film comprising:
delivering a first precursor which provides a source of silicon to a deposition chamber;
delivering a second precursor which provides a source of carbon to the deposition chamber; and
delivering a source of nitrogen to the deposition chamber, thereby forming a carbon doped silicon nitride film.

2. The method of claim 1, including the delivering of oxygen to the chamber.

3. The method defined by claim 1, wherein the first precursor is a silane based compound.

4. The method of claim 1, wherein the first precursor is selected from the group consisting of halogenated silanes, disilanes, amino silanes, cyclodisilazanes, linear and branched silazanes, azidosilanes, disilacyclohexane, and silyl hydrazines.

5. The method defined by claim 2, wherein the first precursor is a silane based compound.

6. The method defined by claim 2, wherein the first precursor is selected from the group consisting of halogenated silanes, disilanes, amino silanes, cyclodisilazanes, linear and branched silazanes, azidosilanes, disilacyclohexane, and silyl hydrazines.

7. The method defined by claim 3, wherein the source of nitrogen comprises ammonia.

8. The method defined by claim 5, wherein the source of nitrogen comprises ammonia.

9. The method defined by claim 1, wherein the second precursor is selected from the group consisting of alkyl silanes, alkyl polysilanes, halogenated alkyl silanes, carbon bridge silane, silyl ethane, and silyl ethylene.

10. The method defined by claim 2, wherein the second precursor is selected from the group consisting of alkyl silanes, alkyl polysilanes, halogenated alkyl silanes, carbon bridge silane, silyl ethane, and silyl ethylene.

11. A method for fabricating insulative layers in a semiconductor device comprising:
forming a first silicon nitride layer;
forming a second silicon nitride layer adjacent to the first layer; and
adjusting the carbon content in at least one of the first and second layers so that one of the first and second layers etches more quickly in the presence of a first etchant.

12. The method defined by claim 11, wherein the forming of at least one of the first and second layers comprises:
delivering a first precursor which provides a source of silicon to a deposition chamber;
delivering a second precursor which provides a source of carbon to the deposition chamber; and
delivering a source of nitrogen to the deposition chamber.

13. The method defined by claim 12, wherein the first precursor is a silane based compound.

14. The method defined by claim 12, wherein the first precursor is selected from the group consisting of halogenated silanes, disilanes, amino silanes, cyclodisilazanes, linear and branched silazanes, azidosilanes, disilacyclohexane, and silyl hydrazines.

15. The method defined by claim 12, wherein the source of nitrogen comprises ammonia.

16. The method defined by claim 12, wherein the second precursor is selected from the group consisting of alkyl silanes, alkyl polysilanes, halogenated alkyl silanes, carbon bridge silane, silyl ethane, and silyl ethylene.

17. The method defined by claim 12, including the delivering of oxygen to the chamber.

18. The method defined by claim 17, wherein the first precursor is a silane based compound.

19. The method defined by claim 18, wherein the first precursor is selected from the group consisting of halogenated silanes, disilanes, amino silanes, cyclodisilazanes, linear and branched silazanes, azidosilanes, disilacyclohexane, and silyl hydrazines.

20. A semiconductor substrate including:
a first region comprising a first silicon nitride material having a first carbon content;
a second region comprising a second silicon nitride material having a second carbon content, different than the first carbon content; and
both the first and second regions being arranged on the substrate such that both are exposed to an etchant during an etching process, the etchant etching one of the first and second regions more quickly than the other.

21. The substrate of claim 20, wherein at least one of the first and second silicon nitride regions includes oxygen.

22. The substrate of claim 20, wherein one of the first and second regions is a sidewall spacer.

23. The substrate of claim 20, wherein one of the first and second regions is a mask.

24. A process for fabricating a semiconductor device comprising:
adjusting the relative carbon content in two adjacent silicon nitride regions; and
exposing the silicon nitride regions to an etchant, such that one of the regions etches more quickly than the other.

25. The process defined by claim 24, wherein one of the adjacent regions is a sidewall spacer.

26. The process defined by claim 24, wherein one of the adjacent regions is a mask.
